(19) United States
(12) Patent Application Publication
(10) Pub. No.: US 2010/0159681 A1
(43) Pub. Date: Jun. 24, 2010

(54) Ion implantation method and method for manufacturing semiconductor apparatus

(75) Inventor: Naoto Tsumura, Osaka-shi (JP)

Correspondence Address: EDWARDS ANGELL PALMER & DODGE LLP, P.O. BOX 55874, BOSTON, MA, 02205, US

(73) Assignee: Sharp Kabushiki Kaisha, Osaka-shi (JP)

(21) Appl. No.: 12/654,402

(22) Filed: Dec. 18, 2009

(30) Foreign Application Priority Data
Dec. 18, 2008 (JP) 2008-322914

(51) Int. Cl. H01L 21/266

(52) U.S. Cl. 438/527; 257/E21.346

(57) ABSTRACT

An ion implantation method according to the present invention is provided, to selectively implant ions in a semiconductor area, which is a semiconductor substrate or a semiconductor layer formed on the semiconductor substrate, using an ion implantation mask, the method including the steps of: forming the ion implantation mask by exposing and developing of a photosensitive material film, in such a manner that the ion implantation mask includes a mask opening and a mask thin film section; and implanting ions using the ion implantation mask as a mask to form a plurality of diffusion layers with different diffusion depths in the semiconductor area corresponding to the mask opening section and the mask thin film section.

This nonprovisional application claims priority under 35 U.S.C. §119(a) to Patent Application No. 2008-322914 filed in Japan on Dec. 18, 2008, the entire contents of which are hereby incorporated by reference.

### BACKGROUND OF THE INVENTION

1. Field of the Invention

The present invention is related to an ion implanting method and a method for manufacturing a semiconductor apparatus, and more particularly, to an ion implanting method that adjusts a profile of an ion implanting area using a difference in level of a resist film as an ion implantation mask, and a method for manufacturing a semiconductor apparatus using the ion implanting method.

2. Description of the Related Art

In the conventional manufacturing process of a semiconductor apparatus, a diffusion layer, which constitutes an element such as a transistor, is formed by ion implantation on a surface area of a semiconductor substrate.

FIG. 8 is a diagram schematically illustrating a structure of a conventional semiconductor apparatus.

A semiconductor apparatus 200 includes first diffusion layers 11a formed in such a manner to face a surface area of a semiconductor substrate 1; and a second diffusion layer 11b formed in between the first diffusion layers 11a. The second diffusion layer 11b is formed such that its depth from the surface of the substrate is shallower than the depth of the first diffusion layers 11a. FIG. 8 illustrates only the semiconductor substrate 1, which constitutes the semiconductor apparatus, and the diffusion layer of the surface area. However, the actual semiconductor apparatus includes electrodes and wiring, which constitute a plurality of elements and are formed on the semiconductor substrate having such a diffusion layer formed therein. Further, the electrodes and wiring corresponding to the respective elements are electrically insulated by an interlayer insulation film so that necessary electric circuits are formed by the elements.

Next, a method for manufacturing the above semiconductor apparatus will be described with reference to FIGS. 9 to 11.

FIG. 9 is a diagram describing an exposure mask used in a photolithography step in the method for manufacturing the above semiconductor apparatus, illustrating exposure masks M11 and M12 with different exposure patterns (FIGS. 9(a) and 9(b)). FIGS. 10(a) to 10(c) each illustrate a step of forming the first diffusion layers 11a by ion implantation. FIGS. 11(a) to 11(c) each illustrate a step of forming the second diffusion layer 11b by ion implantation.

First, the exposure mask used in the ion implantation step will be briefly described.

The exposure mask M11 illustrated in FIG. 9(a) includes mask openings A1, which oppose each other. The mask openings A1 correspond to the first diffusion layers 11a in the semiconductor apparatus 200. The exposure mask M12 illustrated in FIG. 9(b) includes one mask opening A2. The mask opening A2 corresponds to the second diffusion layer 11b in the semiconductor apparatus 200. These exposure masks are formed by a chromium layer 4 adhered on a surface of a glass substrate 3 as a light shielding film, and the mask openings A1 and A2 are portions 4a from which the chromium film 4 is selectively removed (see FIGS. 10(a) and 11(a)). In addition, portions B1 and B2, where the chromium film 4 of the exposure masks M11 and M12 remain, function as a light shielding section.

Next, the method for manufacturing the semiconductor apparatus, and in particular, a step of forming the diffusion layer will be described.

A resist film 2 is formed by applying a photoresist material (photosensitive material) on the semiconductor substrate 1. Subsequently, the exposure mask M11 is positioned with respect to the semiconductor substrate 1, and exposure light 5 is irradiated onto the surface of the semiconductor substrate 1 via the exposure mask M11. Thus, an exposure section R1 is formed in an area of the resist film 2, which corresponds to the opening A1 of the mask M11, (FIG. 10(a)).

Next, the exposure section R1 is removed by developing the resist film 2 to form a resist opening 2a. Subsequently, ions 7 are implanted as either p-type or n-type dopant using the resist film 2 as an ion implantation mask (FIG. 10(b)), and the resist film 2 is peeled off. Thus, the first diffusion layers 11a are formed on the surface area of the semiconductor substrate 1 (FIG. 10(c)).

Subsequently, a resist film 20 is formed by applying a resist material on the semiconductor substrate 1, and the exposure mask M12 is positioned with respect to the semiconductor substrate 1 to irradiate exposure light 5 onto the surface of the semiconductor substrate 1 via the exposure mask M12. Thus, an exposure section R2 is formed in an area of the resist film 20, which corresponds to the opening A2 of the mask M12, (FIG. 11(a)).

Next, the exposure section R2 is removed by developing the resist film 20 to form a resist opening 20a. Subsequently, ions 9 are implanted as either p-type or n-type dopant using the resist film 20 as an ion implantation mask (FIG. 11(b)), and the resist film 20 is removed. Thus, the second diffusion layer 11b is formed on the surface area of the semiconductor substrate 1 (FIG. 11(c)).

As described above, in the step of forming the diffusion layer in the conventional method for manufacturing the semiconductor apparatus, the diffusion layers with different depths are formed by separate ion implantation processes using different ion implantation masks corresponding to the respective layers.

Thus, it is necessary to perform the steps of exposing, implanting ions and peeling off a resist twice, as illustrated in FIGS. 10 and 11, in order to obtain the diffusion layer illustrated in FIG. 8, or namely an ion implantation layer in the substrate. This results in some problems, such as requiring a longer TAT (turn around time), that is a time for manufacturing the semiconductor apparatus, increasing the cost for materials, and not securing an appropriate alignment accuracy between the first and second resist films.

The following References 1 to 3 describe techniques related to the simplification of processes in the manufacturing of semiconductors.

Reference 1 discloses a method for forming a diffusion resist layer on a substrate, in which a photoresist film is formed as an ion implantation mask in such a manner that a height difference section of an oxide film as base positions in an opening of the resist film, and the diffusion resist layer with varied thicknesses is formed in the surface area of the substrate using the photoresist film and oxide film as ion implantation masks. In the disclosed method of Reference 1, a diffusion layer with varied thicknesses is formed in one ion implantation step.

Further, Reference 2 discloses a method for manufacturing a semiconductor apparatus, in which a resist film with a height difference section is formed on a polycrystalline silicon film, and the polycrystalline silicon film is etched using the resist film as a mask to transfer the height differences of the resist film to the polycrystalline silicon film.

Further, Reference 3 discloses a method for manufacturing a semiconductor apparatus, as similar to Reference 2 described above. In the method, an insulation film and a semiconductor layer are formed on a substrate, and subsequently, a thin first conductive layer and a thick second conductive layer are successively formed with an insulation film interposed therebetween. A resist film having a thick portion and a thin portion is formed thereabove. The first and second conductive layers are etched using the resist film as a mask to form a gate electrode with a height difference, consisted of the first and second conductive layers. Subsequently, ions are implanted passing through the thin portion of the gate electrode, and impurity ions are implanted in a semiconductor layer on the lower side of the gate electrode to form an LDD (lightly doped drain) structure.

In References 1 to 3, an oxide film or a conductive layer having a height difference is used as an ion implantation mask, thereby forming a diffusion layer with different depths in one ion implantation. In Reference 2, a resist film with a height difference is formed on a polycrystalline silicon film to be subsequently etched back entirely. As a result, a gate electrode with a height difference is formed, thereby simplifying the formation of such a gate electrode with a height difference.

Reference 1: Japanese Laid-Open Publication No. 61-85854

Reference 2: Japanese Laid-Open Publication No. 10-32327

Reference 3: Japanese Laid-Open Publication No. 2007-19490

### SUMMARY OF THE INVENTION

As described above, in the conventional methods for manufacturing the semiconductor apparatus, the diffusion layers with different depths are formed by separate ion implantation processes using different ion implantation masks corresponding to the respective layers.

Thus, it is necessary to perform twice the steps of exposing, implanting ions and removing a resist, as illustrated in FIGS. 10 and 11, in order to obtain the diffusion layer illustrated in FIG. 8, or namely an ion implantation area in the substrate. This results in some problems, such as requiring a longer TAT, increasing the cost for materials, and not securing appropriate alignment accuracy between the first and second resist films.

Further, in References 1 to 3, although it is possible to simplify the manufacturing process, there is a problem of not being able to directly reflect the thickness of the resist film on the depth of the diffusion layer.

The present invention is intended to solve the conventional problems described above. The objective of the present invention is to provide an ion implantation method, in which a thickness of a resist film as an ion implantation mask can be directly reflected on a depth of a diffusion layer, to form a plurality of diffusion layers in a simple step, thereby reducing a manufacturing period (TAT) of the semiconductor apparatus, cutting a manufacturing cost for the semiconductor apparatus, and increasing alignment accuracy between two diffusion layers; and a method for manufacturing a semiconductor apparatus using the ion implantation method.

An ion implantation method according to the present invention for selectively implanting ions in a semiconductor area, which is a semiconductor substrate or a semiconductor layer formed on a semiconductor substrate, using an ion implantation mask, is provided, the method including the steps of: forming the ion implantation mask by exposing and developing of a photosensitive material film, in such a manner that the ion implantation mask includes a mask opening and a mask thin film section; and implanting ions using the ion implantation mask as a mask to form a plurality of diffusion layers with different diffusion depths in the semiconductor area corresponding to the mask opening section and the mask thin film section, thereby achieving the objective described above.

Preferably, in an ion implantation method according to the present invention, in the step of implanting ions, a first diffusion layer with a deep diffusion depth is formed in a portion of the semiconductor area corresponding to the mask opening of the ion implantation mask, and a second diffusion layer with a shallow diffusion depth is formed in a portion of the semiconductor area corresponding to the mask thin film section of the ion implantation mask.

Still preferably, in an ion implantation method according to the present invention, the diffusion depth of the second diffusion layer is a depth in accordance with a thickness of the mask thin film section of the ion implantation mask.

Still preferably, in an ion implantation method according to the present invention, the mask thin film section is constituted of a plurality of thin film portions with different film thicknesses.

Still preferably, in an ion implantation method according to the present invention, the mask thin film section is constituted of a first thin film portion with a first film thickness, and a second thin film portion with a second film thickness, which is different from the first film thickness.

Still preferably, in an ion implantation method according to the present invention, the mask thin film section is formed such that the second thin film portion is thinner than the first thin film portion, and the film thickness of the second thin film portion either decreases or increases incrementally from one end to the other end.

Still preferably, in an ion implantation method according to the present invention, the mask thin film section is formed such that the second thin film portion is thinner than the first thin film portion, and the film thickness of the second thin film portion either decreases or increases successively from one end to the other end.

Still preferably, in an ion implantation method according to the present invention, the mask thin film section has a structure such that the film thickness of the mask thin film section either decreases or increases incrementally from one end to the other end.

Still preferably, in an ion implantation method according to the present invention, the mask thin film section has a structure such that the film thickness of the mask thin film section either decreases or increases successively from one end to the other end.

Still preferably, in an ion implantation method according to the present invention, the photosensitive material is a positive type resist in which a portion exposed to exposure light is removed by developing; and in the step of exposing and developing of the photosensitive material film, the positive type resist formed on the semiconductor area is exposed and developed using an exposure mask including a light passing section for allowing the exposure light to pass through and a translucent section for decreasing the exposure light, to form a resist film, as the ion implantation mask, including a resist opening corresponding to the light passing section and a resist thin film section corresponding to the translucent section.

Still preferably, in an ion implantation method according to the present invention, the exposure mask includes the translucent section for decreasing the exposure light, in which a half tone mask for decreasing the exposure light evenly over the entire translucent section is used in the translucent section.

Still preferably, in an ion implantation method according to the present invention, the exposure mask is formed such that a light shielding film for shielding the exposure light is selectively formed on a transparent substrate, which is constituted of a transparent member that allows the exposure light to pass through.

Still preferably, in an ion implantation method according to the present invention, the exposure mask has a structure such that the light passing section is defined as the opening of the light shielding film and the translucent section is formed by alternately arranging light passing areas, from which the light shielding film is removed, and light shielding areas, in which the light shielding film remains, lengthwise and widthwise.

Still preferably, in an ion implantation method according to the present invention, the exposure mask has a structure such that the light passing section is defined as the opening of the light shielding film and the translucent section is formed by alternately arranging stripe-formed light passing areas, from which the light shielding film is removed, and stripe-formed light shielding areas, in which the light shielding film remains, in a given direction.

Still preferably, in an ion implantation method according to the present invention, in the step of implanting ions, a plurality of diffusion layers with different diffusion depths are formed by the ion implantation by a constant implantation energy.

Still preferably, in an ion implantation method according to the present invention, in the step of implanting ions, ion implantation is performed a plurality of times by changing at least one of the implantation energy and an ion type, using the same ion implantation mask.

A method for manufacturing a semiconductor apparatus including a plurality of elements according to the present invention is provided, the method including an ion implantation step of selectively implanting ions in a semiconductor area, which is a semiconductor substrate or a semiconductor layer formed on the semiconductor substrate, using an ion implantation mask, to form a diffusion layer, which constitutes the elements, in the semiconductor area, the ion implanting step comprising the steps of : forming the ion implantation mask by exposing and developing of a photosensitive material film, in such a manner that the ion implantation mask includes a mask opening and a mask thin film section; and implanting ions using the ion implantation mask as a mask to form a plurality of diffusion layers with different diffusion depths in the semiconductor area corresponding to the mask opening section and the mask thin film section, thereby achieving the objective described above.

The functions of the present invention will be described hereinafter.

In the present invention, by exposing and developing the photosensitive material film formed on the semiconductor substrate or the semiconductor area, which is a semiconductor layer above the semiconductor substrate, the ion implantation mask is formed in such a manner to include a mask opening section and a mask thin film section formed therewith. Subsequently, ions are implanted using the ion implantation mask as a mask to form a plurality of diffusion layers with different diffusion depths in the semiconductor area, by corresponding to the mask opening section and the mask thin film section. As a result, the plurality of diffusion layers with different concentration profiles can be formed in one photolithography step and one ion implantation step, thereby reducing a manufacturing period (TAT) of the semiconductor apparatus, cutting a manufacturing cost for the semiconductor apparatus, and increasing alignment accuracy between two diffusion layers.

Further, in the present invention, the exposure mask is formed by selectively forming a light shielding film for shielding exposure light on a transparent substrate formed of a transparent member, allowing the exposure light to pass through. A translucent section of the exposure mask is structured by alternately arranging light passing areas, from which the light shielding film is removed, and light shielding areas, in which the light shielding film remains, to form a check pattern, so that the light shielding portion of the exposure mask and the light shielding area in the translucent section can be formed of the same light shielding film material, such as a chromium film. As a result, the structure of the exposure mask with the translucent section can be simplified, and further, the materials for the structure can be only a glass substrate and a light shielding film material.

Further, in the present invention, the light shielding film for shielding the exposure light is selectively formed on the transparent substrate formed of a transparent member, allowing the exposure light to pass through. The translucent section of the exposure mask is structured by alternately arranging stripe-formed light passing areas, from which the light shielding film is removed, and stripe-formed light shielding areas, in which the light shielding film remains, in a given direction, so that the light shielding portion of the exposure mask and the light shielding area in the translucent section can be formed of the same light shielding film material, such as a chromium film. As a result, the structure of the exposure mask with the translucent section can be simplified, and further, the materials for the structure can be only a glass substrate and a light shielding film material.

According to the present invention as described above, in the ion implantation method for selectively implanting ions using an ion implantation mask in the semiconductor substrate or the semiconductor area, which is a semiconductor layer formed on the semiconductor substrate, the method includes a step of forming the ion implantation mask by exposing and developing of the photosensitive material film in such a manner that the ion implantation mask includes a mask opening and a mask thin film section; and a step of implanting ions using the ion implantation mask as a mask to form the plurality of diffusion layers with different diffusion depths in the semiconductor area by corresponding to the mask opening section and the mask thin film section. As a result, it is possible to achieve effects, such as reducing a manufacturing period (TAT) of the semiconductor apparatus, cutting a manufacturing cost for the semiconductor apparatus, and increasing alignment accuracy between two diffusion layers.

These and other advantages of the present invention will become apparent to those skilled in the art upon reading and understanding the following detailed description with reference to the accompanying figures.

### BRIEF DESCRIPTION OF THE DRAWINGS

FIG. 1 is a diagram describing a method for manufacturing a semiconductor apparatus according to Embodiment 1 of the present invention, where a cross sectional structure of the semiconductor apparatus at the point when an ion implanting step is completed is illustrated together with an ion implantation mask used in the ion implanting step.

FIG. 2 is a diagram describing a method for manufacturing a semiconductor apparatus according to Embodiment 1 of the present invention, and further, a diagram describing an exposure mask used in a patterning step of a resist film, illustrating an exposure mask M1 used in Embodiment 1 (FIG. 2(a)) and another exposure mask M2 used instead of the exposure mask M1 (FIG. 2(b)).

FIG. 3 is a diagram describing a method for manufacturing a semiconductor apparatus according to Embodiment 1 of the present invention, and further, a diagram describing an exposure mask used in a patterning step of a resist film, further illustrating an exposure mask M3 (FIG. 3(a)) and an exposure mask M4 (FIG. 3(b)) used instead of the exposure mask illustrated in FIG. 2.

FIG. 4 is a diagram describing a method for forming an ion implantation mask in a sequence of steps, illustrating a step of applying a resist material (FIG. 4(a)), a step of exposing (FIG. 4(b)) and a step of developing (FIG. 4(c)).

FIG. 5 is a diagram illustrating selective ion implantation using an ion implantation mask, illustrating a step of implanting ions (FIG. 5(a)) and a step of removing a resist film (FIG. 5(b)).

FIG. 6 is a diagram describing a method for manufacturing a semiconductor apparatus according to Embodiment 2 of the present invention, where FIG. 6(a) illustrates a cross sectional structure of a semiconductor apparatus at the point when an ion implantation step is completed and FIG. 6(b) illustrates an exposure mask of a resist film.

FIG. 7 is a diagram describing a method for manufacturing a semiconductor apparatus according to Embodiment 3 of the present invention, where FIG. 7(a) illustrates a cross sectional structure of the semiconductor apparatus at the point when an ion implantation step is completed and FIG. 7(b) illustrates an exposure mask of a resist film.

FIG. 8 is a diagram schematically illustrating a structure of a conventional semiconductor apparatus.

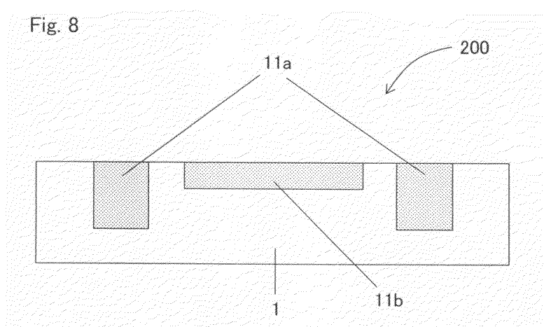

FIG. 9 is a diagram describing an exposure mask used in a photolithography step in the method for manufacturing the above semiconductor apparatus, illustrating exposure masks M11 and M12 with different exposure patterns (FIGS. 9(a) and 9(b)).

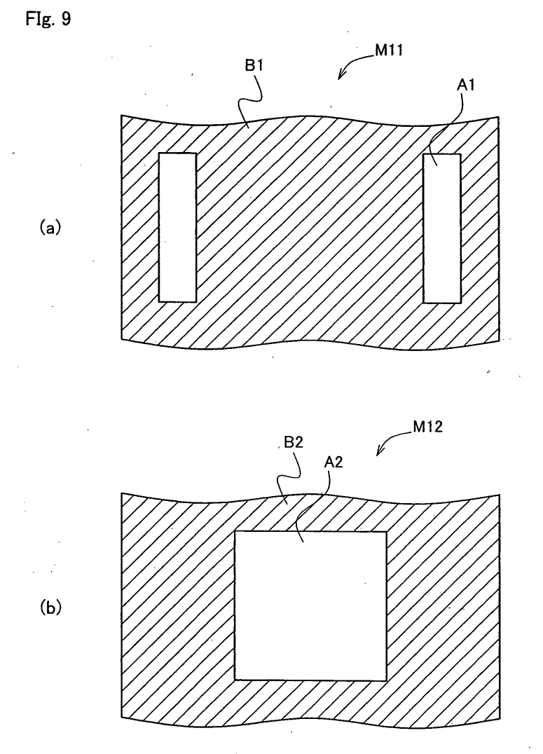

FIGS. 10(a) to 10(c) each illustrate a step of forming the first diffusion layers 11a by ion implantation.

FIGS. 11(a) to 11(c) each illustrate a step of forming the second diffusion layer 11b by ion implantation.

1 semiconductor substrate

1a first diffusion layer

1b second diffusion layer

1c, 1d third diffusion layer

3 transparent substrate

4 light shielding film

4a light shielding film opening

4b translucent section

5, 6 exposure light

7, 9 ion implantation

11a first diffusion layer

11b second diffusion layer

12, 22, 32 ion implantation mask (resist film)

12a, 22a, 32a mask opening

12b, 22b, 32b, 32c resist thin film section

A light passing section

B light shielding section

Bp2, Bp3 light shielding small area

M1 to M4, M4a, M4b exposure mask

P1 to P4, P4a, P4b translucent section

R1, R2 exposure section (photosensitive section)

Tp2, Tp3 transparent small area

Tp11 to Tp13, Tpa to Tpd, Tpg area

### DESCRIPTION OF THE PREFERRED EMBODIMENTS

Hereinafter, embodiments of the present invention will be described with reference to the accompanying figures.

### Embodiment 1

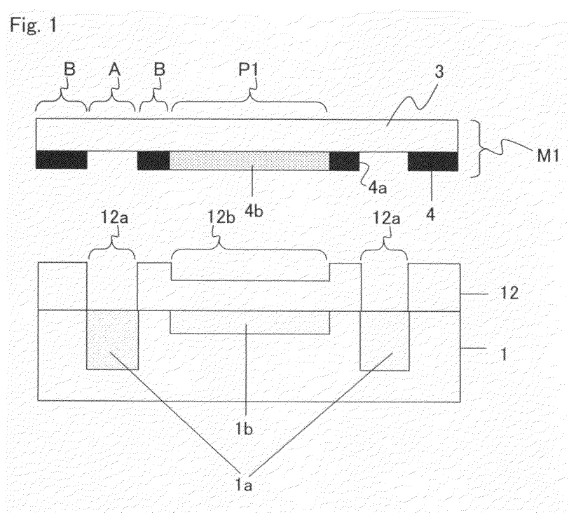

FIG. 1 is a diagram describing a method for manufacturing a semiconductor apparatus according to Embodiment 1 of the present invention, where a cross sectional structure of the semiconductor apparatus at the point when an ion implanting step is completed is illustrated together with an ion implantation mask used in the ion implanting step.

At the point when the ion implanting step is completed as illustrated in FIG. 1, first diffusion layers (that is, ion implanting areas) 1a are formed in a surface area of a semiconductor substrate 1, which is a silicon substrate or the like that constitutes the semiconductor apparatus, in such a manner that the first diffusion layers 1a oppose each other; and a second diffusion layer (that is, ion implanting area) 1b is formed in the surface area of the semiconductor substrate 1 in such a manner to be positioned in between the first diffusion layers 1a. The second diffusion layer 1b is formed such that the depth of the second diffusion layer 1b from the surface of the substrate is shallower than the depth of the first diffusion layers 1a. For example, the depth of the first diffusion layers 1a is between 2 μm and 4 μm, and is typically 3 μm. The depth of the second diffusion layer 1b is between 0.5 μm and 2 μm, and is typically 1 μm. The semiconductor substrate is defined to be a silicon substrate herein; however, the semiconductor substrate may be formed of a different semiconductor material. Further, the diffusion layer is not limited to be formed in the surface area of the semiconductor substrate; however, the diffusion layer may be formed in the surface area of the semiconductor layer formed on a substrate.

In addition, at this stage, an ion implantation mask 12 for selectively implanting ions in the semiconductor substrate 1 is formed on the semiconductor substrate 1 so that each of the diffusion layers 1a and 1b are formed. Although not shown, an oxide film and the like are formed as an ion implantation protecting film on the surface of the substrate, and the resist film as an ion implantation mask is formed on the oxide film.

The ion implantation mask 12 is a resist film formed by a photolithography step, including applying, exposing and developing a resist material. The resist film 12 includes mask openings 12a for forming the first diffusion layers 1a in such a manner to oppose each other, and a thin film section 12b with a thin film thickness is formed in between the mask openings 12a to form the second diffusion layer 1b. The film thickness of the resist film 12 as an ion implantation mask is between 3 μm and 5 μm, and preferably, is about 4 μm. In addition, the thickness of the thin film section 12b is between 2.5 μm and 1 μm, and preferably, is about 2 μm.

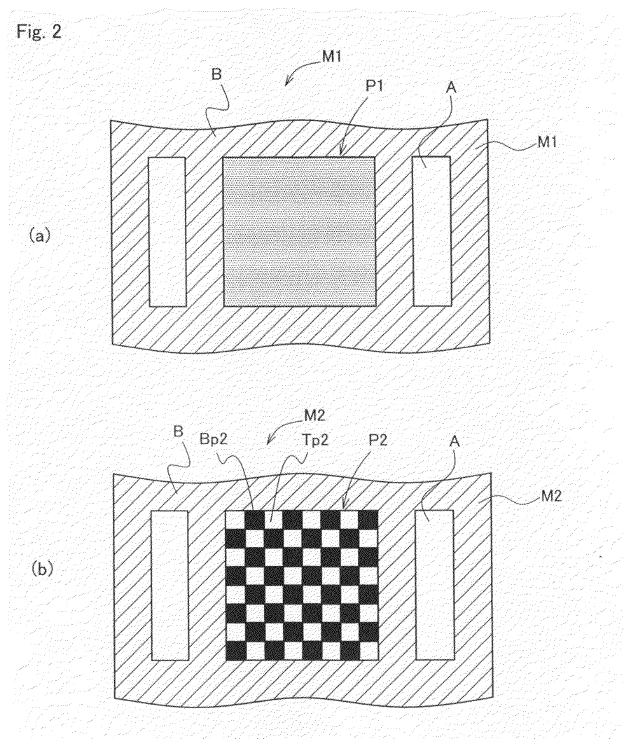

Further, the exposure mask M1 illustrated in FIGS. 1 and 2(a) is used in the photolithography step of forming the ion implantation mask 12.

The exposure mask M1 is formed by adhering a light shielding film 4 on a surface of a transparent substrate 3, such as a glass substrate, that allows exposure light to pass through. The exposure mask M1 includes light passing sections A for completely passing the exposure light through; a light shielding section B for preventing the exposure light from passing through; and a translucent section P1 for decreasing the exposure light to be passed through. More specifically, the light passing sections A of the exposure mask M1 are light shielding film openings 4a formed in the light shielding film 4; and the translucent section P1 of the exposure mask M1 is structured such that a member (for example, a light decreasing member, such as a half tone light shielding member) 4b for decreasing the exposure light to be passed through is positioned at a portion where the light shielding film 4 is partially removed. Ultraviolet light with the wavelength of about 436 nm to 248 nm is used as the exposure light. Further, molybdenum silicide, tantalum silicide or the like is used for the member 4b for decreasing the exposure light to be passed through. Further, the light passing sections A and translucent section P1 respectively include a layout pattern corresponding to the resist openings 12a for forming the first diffusion layers 1a and a layout pattern corresponding to the resist thin film section 12b for forming the second diffusion layer 1b. A common positive resist for exposing ultraviolet light is used as the resist material; and a semiconductor laser, metal halide lamp, high-pressure mercury vapor lamp, or the like can be used as a light source of the exposure light.

Next, a method for manufacturing the semiconductor apparatus will be described.

In the method for manufacturing the semiconductor apparatus according to Embodiment 1, the manufacturing method is the same as the conventional method for manufacturing the semiconductor apparatus, except for a step of forming an ion implantation mask using a photolithography technique to form a diffusion layer by ion implantation. Thus, a step of forming an ion implantation mask and a step of forming a diffusion layer will be described hereinafter.

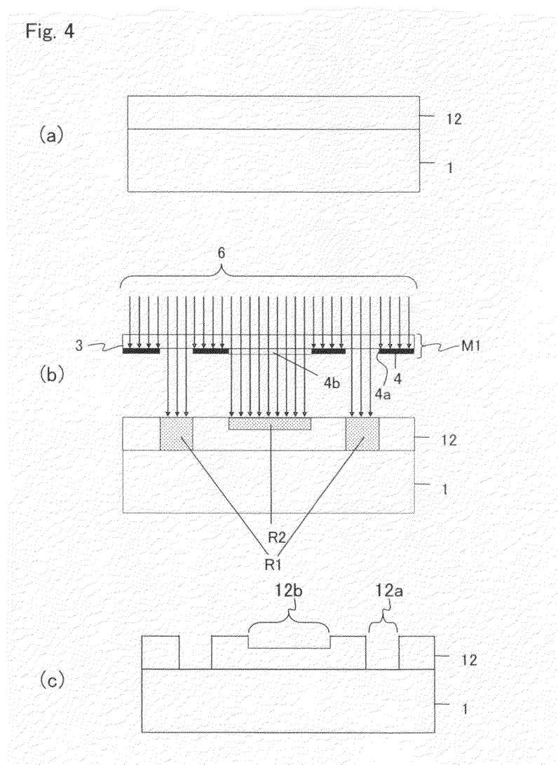

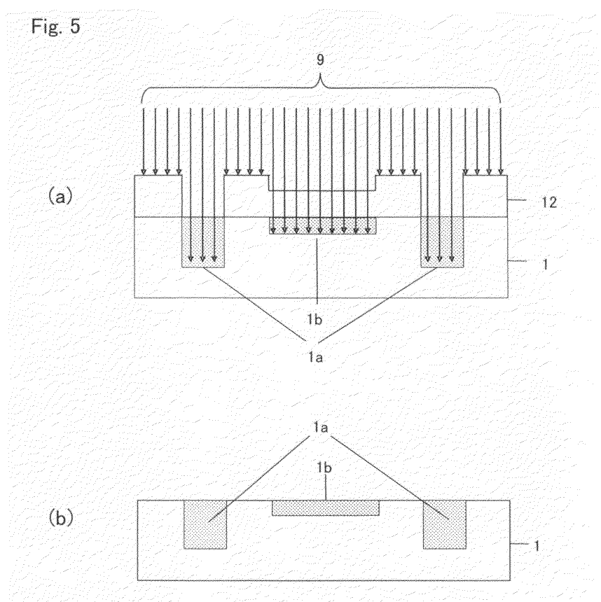

FIG. 4 is a diagram describing a method for forming an ion implantation mask in a sequence of steps, illustrating a step of applying a resist material (FIG. 4(a)), a step of exposing (FIG. 4(b)) and a step of developing (FIG. 4(c)). Further, FIG. 5 is a diagram illustrating selective ion implantation using the ion implantation mask, illustrating a step of implanting ions (FIG. 5(a)) and a step of removing a resist film (FIG. 5(b)).

First, the resist film 12 is formed on the semiconductor substrate 1, such as a silicon substrate, by applying a positive resist material (photosensitive material) thereon (FIG. 4(a)).

Next, the exposure mask M1 is positioned with respect to the semiconductor substrate 1, and exposure light 6 is irradiated on the surface of the semiconductor substrate 1 through the exposure mask M1 to selectively expose the resist film 12 (FIG. 4(b)). At this stage, in the portion of the resist film 12 which corresponds to the translucent section P1 (light decreasing member 4b) of the exposure mask M1, the resist film 12 is not completely exposed up to an interface of the substrate. As a result, a complete exposure section R1 is formed in the area of the resist film 12 corresponding to each light passing section A of the mask M1, and an exposure section R2 with a depth shallower than that of the exposure section R1 is formed in the area of the resist film 12 corresponding to the translucent section P1 of the mask M1.

Subsequently, the exposure sections (photosensitive areas) R1 and R2 of the resist film 12 are removed by a developing process of the resist film 12, and the opposing resist openings 12a and the resist thin film section 12b positioned in between the resist openings 12a are formed in the resist film 12 (FIG. 4(c)).

Next, ions 9 are implanted as either p-type or n-type dopant using the resist film 12 as an ion implantation mask (FIG. 5(a)). In this case, the ions are implanted deep in the substrate at a portion corresponding to the resist opening 12a on the surface of the semiconductor substrate, whereas the ions, which are implanted in a portion corresponding to the resist thin film section 12b of the surface of the semiconductor substrate, penetrate the resist film to be implanted in a shallow portion of the surface of the substrate because the portion corresponding to the resist thin film section 12b of the surface of the semiconductor substrate is thinner than the resist film thickness of other portions. The type of the ions at this stage is boron (B), for example. Further, the implantation energy is between 125 KeV and 3000 KeV, and preferably is 2000 KeV.

Subsequently, the resist film 12 is removed. As a result, the first diffusion layers 1a and the second diffusion layer 1b with different depths are formed in the surface area of the semiconductor substrate 1 in one ion implantation step (FIG. 5(b)).

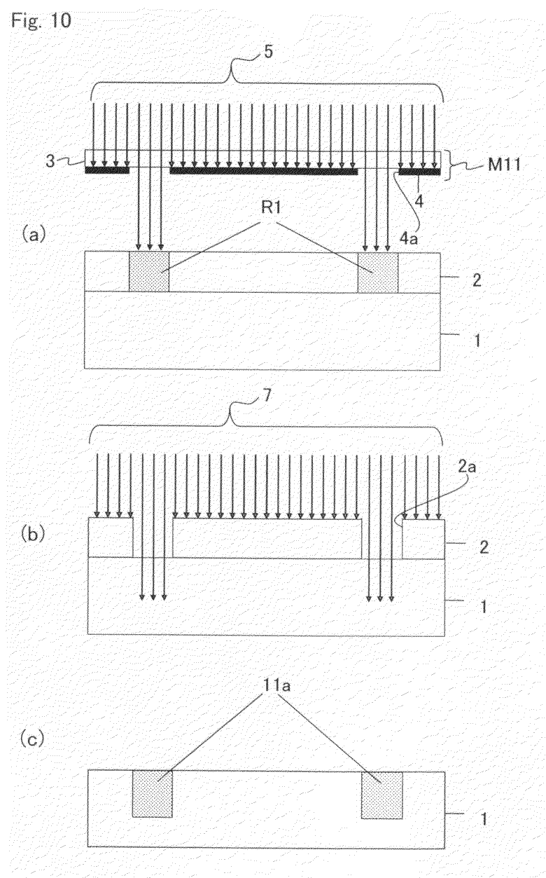

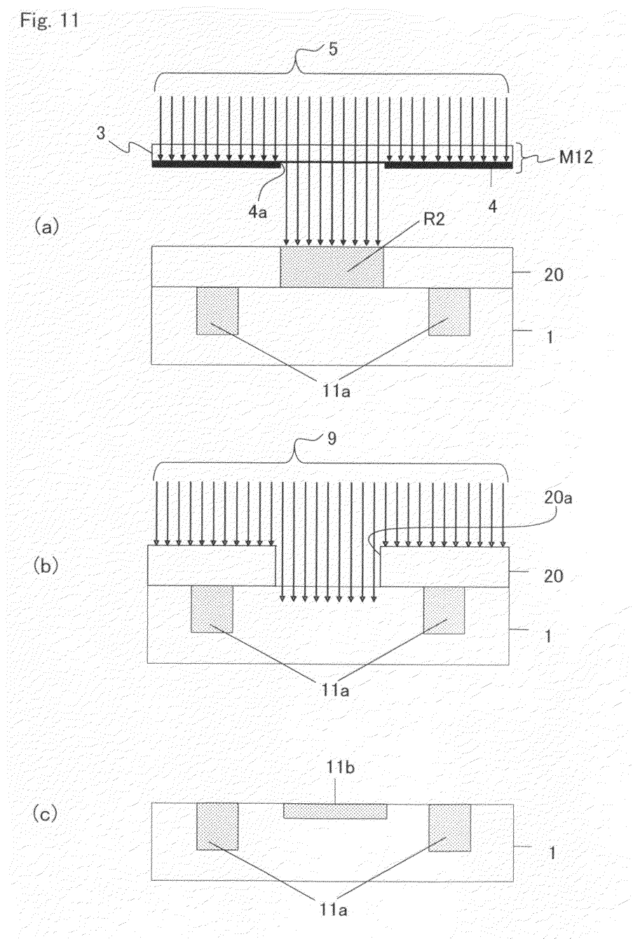

As illustrated in FIGS. 10 and 11, in order to form the two diffusion layers 11a and 11b, the conventional method for manufacturing the semiconductor apparatus requires performing a step of exposing and developing a resist film (FIGS. 10(a) and 11(a)), a step of implanting ions (FIGS. 10(b) and 11(b)), and a step of removing the resist film (FIGS. 10(c) and 11(c)), for each of the first and second diffusion layers 11a and 11b. On the contrary, in the method for manufacturing the semiconductor apparatus according to Embodiment 1, the two diffusion layers 1a and 1b can be formed by performing each of: a step of exposing and developing a resist film (FIGS. 4(a) to 4(c)), a step of implanting ions (FIG. 5(a)), and a step of removing the resist film (FIG. 5(b)) once. Therefore, the number of processing steps is reduced to half compared to the conventional process. Further, reducing the processing steps to half means that the time for TAT (turn around time) (or manufacturing period of the semiconductor apparatus) and the cost for the materials required to form the diffusion layer of the semiconductor apparatus are both reduced to half.

Further, when the first and second diffusion layers are formed using separate ion implantation masks, the alignment accuracy of the respective diffusion layers is influenced by an alignment error between a plurality of pieces of processing equipment, such as an exposure apparatus and an ion implantation apparatus; and an error of positional accuracy in drawing an exposure pattern between exposure masks for forming respective diffusion layers. However, in Embodiment 1, the process of forming the two diffusion layers by ion implantation can be achieved with each of an exposure mask and an ion implantation mask, as illustrated in FIGS. 4 and 5. Thus, the error of positional accuracy in drawing an exposure pattern between exposure masks can be eliminated, thereby improving the alignment accuracy of the two diffusion layers.

According to Embodiment 1 as described above, the resist material applied on the semiconductor substrate 1 is exposed using the exposure mask M1 including the light passing section A and the translucent section P1, and developed. Further, the resist film 12 including the resist openings 12a and the resist thin film section 12b is formed as an ion implantation mask, and ions are implanted in the surface area of the semiconductor substrate using the resist film 12 as a mask to form the first and second diffusion layers 1a and 1b. Thus, the two diffusion layers 1a and 1b with different concentration profiles can be formed in one photolithography step and one ion implantation step, thereby reducing the manufacturing period (TAT) of the semiconductor apparatus, cutting the manufacturing cost for the semiconductor apparatus, and increasing alignment accuracy between the two diffusion layers.

In Embodiment 1, the exposure mask M1 with the translucent section P1 formed of a half tone light shielding member is used for the selective exposure of the resist film, as illustrated in FIG. 2(a). However, the exposure mask of the resist film is not limited to the mask illustrated in FIG. 2(a).

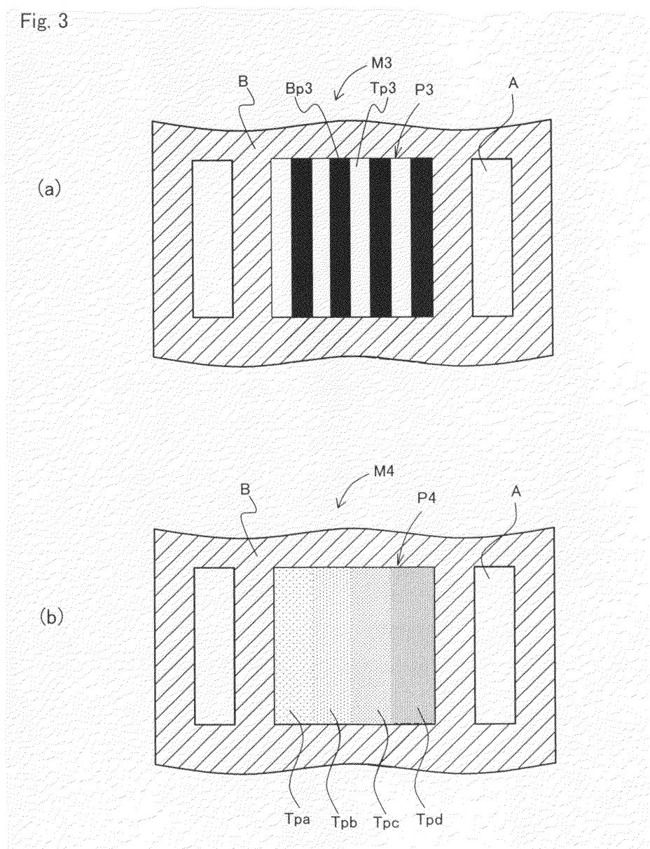

For example, for the selective exposure of the resist film in the step of forming the ion implantation mask in Embodiment 1 described above, the exposure mask M2 illustrated in FIG. 2(b) or the exposure mask M3 illustrated in FIG. 3(a) may be used instead of the exposure mask M1 illustrated in FIG. 2(a).

The exposure mask M2 includes a translucent section P2 with a structure in which light shielding small areas Bp2 for preventing light from passing through and light passing small areas Tp2 for allowing light to pass through are arranged in a hounds tooth check form.

In addition, the exposure mask M3 includes a translucent section P3 with a structure in which stripe-form light shielding small areas Bp3 for preventing light from passing through and stripe-form light passing small areas Tp3 for allowing light to pass through are alternately arranged.

In the exposure mask M2 or M3, the light shielding portion B and the light shielding small area in the translucent section P2 or P3 can be formed of the same light shielding material, for example, a chromium film. As a result, the structure of the exposure mask with the translucent section can be simplified, and further, the materials for the structure can be only a glass substrate and a light shielding film material.

Further, for the selective exposure of the resist film in the step of forming the ion implantation mask in Embodiment 1 described above, an exposure mask M4 illustrated in FIG. 3(b) may be used instead of the exposure masks M1 to M3 illustrated in FIGS. 2(a), 2(b) and 3(a).

The exposure mask M4 includes a translucent section P4, which includes a plurality of areas with different optical transmissivities arranged in a given direction, or four areas Tpa to Tpd herein. In this example, the four areas Tpa to Tpd have decreasing optical transmissivity in this order. Therefore, when the exposure mask 4 is used for the exposing of the resist film, the resist film with incrementally varied thicknesses can be formed as an ion implantation mask, at the portion corresponding to the translucent section P4.

In addition, the exposure mask M4 may include part of the translucent section P4 with incrementally varied optical transmissivity. In this case, the ion implantation mask will have a structure in which the film thickness either increases or decreases incrementally in a part of the mask thin film section from one end side to the other end side.

Hereinafter, a case will be specifically described where an exposure mask with distribution of varied optical transmissivity at a translucent section, such as the exposure mask M4, is used to form an ion implantation mask by exposing and developing of the resist film.

### Embodiment 2

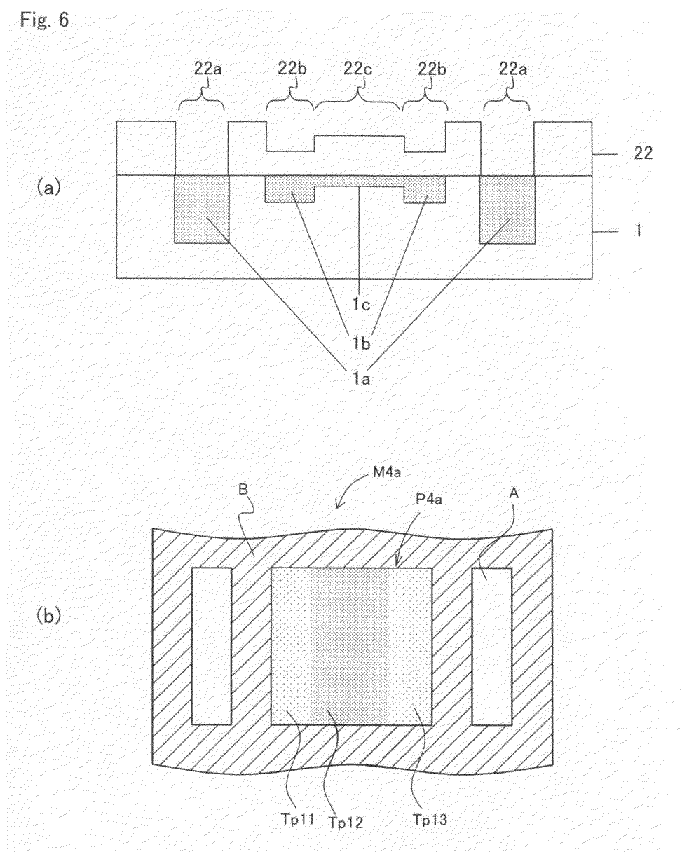

FIG. 6 is a diagram describing a method for manufacturing a semiconductor apparatus according to Embodiment 2 of the present invention, where FIG. 6(a) illustrates a cross sectional structure of a semiconductor apparatus at the point when an ion implantation step is completed and FIG. 6(b) illustrates an exposure mask of a resist film.

In the method for manufacturing the semiconductor apparatus according to Embodiment 2, an exposure mask M4a illustrated in FIG. 6(b) is used in a step of forming a resist film as an ion implantation mask. The exposure mask M4a includes the translucent section P4 illustrated in FIG. 3(b) with varied optical transmissivity in the areas Tpa to Tpd, and a translucent section P4a of the exposure mask M4a includes areas Tp11 and Tp13, which are defined by equalizing the optical transmissivity of the areas Tpa and Tpd on both edges in the mask M4. Further, the optical transmissivity of areas Tpb and Tpc, which are positioned in between the areas Tpa and Tpd and are adjacent to each other, is equalized to be defined as an area Tp12. Further, the optical transmissivity of areas Tp11 and Tp13 is set higher than the optical transmissivity of the area Tp12 in between them.

A resist film 22 on a substrate as illustrated in FIG. 6 (a) is an ion implantation mask obtained by exposing and developing of a resist material using the exposure mask M4a described above. As described in the method for manufacturing the semiconductor apparatus according to Embodiment 1, the ion implantation mask 22 is a resist film manufactured by a photolithography step, including applying, exposing and developing a resist material. The resist film 22 includes mask openings 22a in such a manner to oppose each other, which correspond to light passing sections A of the exposure mask M4a. First and second resist thin film sections 22b and 22c with thin resist film thickness are formed in between the mask openings 22a. The first and second resist thin film sections 22b and 22c correspond to the translucent section P4a of the exposure mask M4a.

The film thickness of the resist film 22 as an ion implantation mask is between 3 μm and 5 μm, for example, about 4 μm. In addition, the thickness of the first resist thin film section 22b is between 1 μm and 2 μm, for example, about 1 μm. The thickness of the second resist thin film section 22c is between 2.5 μm and 2 μm, for example, about 2.2 μm.

By ion implantation to a semiconductor substrate 1 using the resist film 22 as an ion implantation mask in a surface area of the substrate 1, first diffusion layers la are formed at positions corresponding to the resist openings 22a, and second and third diffusion layers 1b and 1c are formed at positions corresponding to the first and second resist thin film sections 22b and 22c.

The second and third diffusion layers 1b and is are both formed such that their depths from the surface of the substrate are shallower than the depth of the first diffusion layers 1a, and the third diffusion layer 1c is formed such that its diffusion depth is shallower than the diffusion depth of the second diffusion layer 1b.

For example, the thickness of the first diffusion layers 1a is between 2 μm and 4 μm, and is typically 3 μm. The thickness of the second diffusion layer 1b is between 1 μm and 2 μm, and is typically 2 μm. The thickness of the third diffusion layer is is between 0.5 μm and 1 μm, and is typically 0.8 μm.

In the method for manufacturing the semiconductor apparatus according to Embodiment 2, the same process as that of Embodiment 1 is performed, except that the structures of the exposure mask used for the exposure of the resist film and the resist film used as an ion implantation mask are different.

According to Embodiment 2 as described above, the resist material applied on the semiconductor substrate 1 is exposed using the exposure mask M4a including the light passing sections A and the translucent section P4a, and developed. Further, the resist film 22 including the resist openings 22a and the first and second resist thin film section 22b and 22c is formed as an ion implantation mask, and ions are implanted in the surface area of the semiconductor substrate using the resist film 22 as a mask to form the first to third diffusion layers 1a to 1c. Thus, the three diffusion layers 1a to 1c with different concentration profiles can be formed in one photolithography step and one ion implantation step, thereby reducing the manufacturing period (TAT) of the semiconductor apparatus, cutting the manufacturing cost for the semiconductor apparatus, and increasing alignment accuracy among the three diffusion layers.

### Embodiment 3

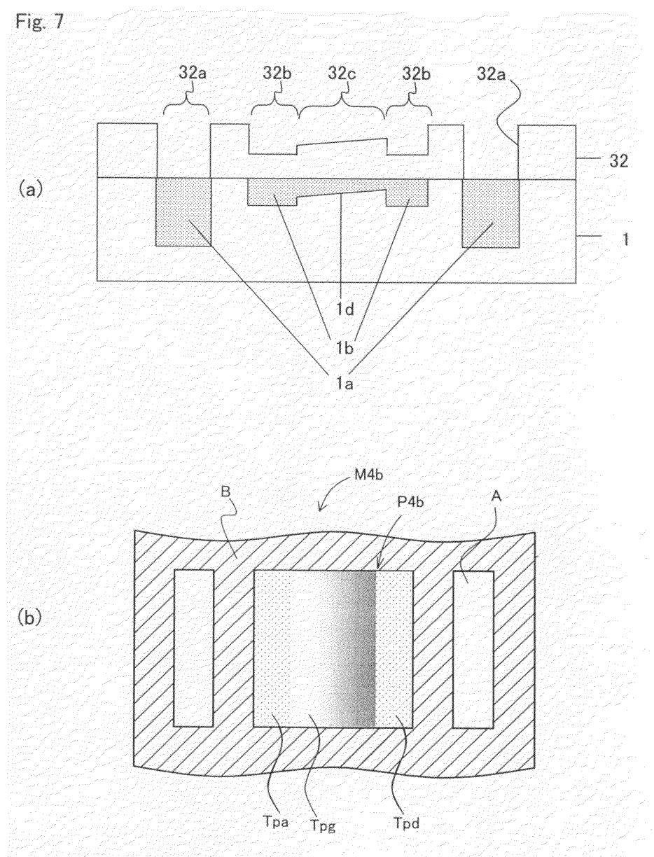

FIG. 7 is a diagram describing a method for manufacturing a semiconductor apparatus according to Embodiment 3 of the present invention, where FIG. 7(a) illustrates a cross sectional structure of the semiconductor apparatus at the point when an ion implantation step is completed and FIG. 7(b) illustrates an exposure mask of a resist film.

In the method for manufacturing the semiconductor apparatus according to Embodiment 3, an exposure mask M4b illustrated in FIG. 7(b) is used in a step of forming a resist film as an ion implantation mask. The exposure mask M4b includes the translucent section P4a of the exposure mask M4a illustrated in FIG. 6(b) with different distribution of optical transmissivity.

In the exposure mask M4b used in Embodiment 3, optical transmissivity of areas Tpa and Tpd on both edges of a translucent section P4b is the same as the optical transmissivity of the exposure mask M4a used in Embodiment 2. However, the exposure mask M4b includes an area Tpg, which is formed by decreasing the optical transmissivity of areas Tpb and Tpc on the center side of the translucent section P4 in the exposure mask M4 successively from the side of the area Tpb to the side of the area Tpc.

A resist film 32 on a substrate as illustrated in FIG. 7 is an ion implantation mask obtained by exposing and developing a resist material using the exposure mask M4b, in which the optical transmissivity is successively varied at the middle portion of the translucent section P4b as described above. The ion implantation mask 32 is, as described in the method for manufacturing the semiconductor apparatus according to Embodiment 1, a resist film formed by a photolithography step, including applying, exposing and developing a resist material. The resist film 32 includes mask openings 32a, which correspond to light passing sections of an exposure mask and are formed in such a manner to oppose each other. In between the mask openings 32a, are formed resist thin film sections 32b with a thin resist film thickness, corresponding to areas Tpa and Tpd on both sides of the translucent section P4b of the exposure mask, as well as a resist thickness varying section 32c with successively varied resist film thickness, corresponding to the area Tpg in the center of the translucent section P4b of the exposure mask.

The film thickness of the resist film 32 as an ion implantation mask is between 3 μm and 5 μm, for example, about 4 μm. In addition, the thickness of the resist thin film section 32b is between 1 μm and 2 μm, for example, about 1 μm. The thickness of the resist thickness varying section 32c varies successively between 1.5 μm and 2.5 μm.

By the ion implantation to a semiconductor substrate 1 using the resist film 32 as an ion implantation mask in a surface area of the substrate 1, first diffusion layers 1a are formed at positions corresponding to the resist openings 32a, and second diffusion layers 1b are formed at positions corresponding to the resist thin film sections 32b. Further, a third diffusion layer id with successively varied diffusion depth, or with an inclined bottom surface, is formed at a portion corresponding to the resist thickness varying section 32c.

The second and third diffusion layers 1b and 1d are both formed such that their depths from the surface of the substrate are shallower than the depth of the first diffusion layers 1a, and the third diffusion layer 1d is formed such that its diffusion depth is shallower than the diffusion depth of the second diffusion layer 1b.

For example, the thickness of the first diffusion layers 1a is between 2 μm and 4 μm, and is typically 3 μm. The thickness of the second diffusion layer 1b is between 1 μm and 2 μm, and is typically 2 μm. The thickness of the third diffusion layer 1d varies between 0.5 μm and 1.5 μm.

In the method for manufacturing the semiconductor apparatus according to Embodiment 3, the same process as that of Embodiment 1 is performed, except that the structures of the exposure mask used for the exposure of the resist film and the resist film used as an ion implantation mask are different.

According to Embodiment 3 as described above, the resist material applied on the semiconductor substrate 1 is exposed using the exposure mask M4b including the light passing sections A and the translucent section P4b with successively varied optical transmissivity in part, and developed. Further, the resist film 32 including the resist openings 32a, the resist thin film section 32b and the resist thickness varying section 32c is formed as an ion implantation mask, and ions are implanted in the surface area of the semiconductor substrate using the resist film 32 as a mask to form the first to third diffusion layers 1a, 1b and 1d. Thus, the three diffusion layers 1a, 1b and 1d with different depth and concentration profiles can be formed in one photolithography step and one ion implantation step, thereby reducing the manufacturing period (TAT) of the semiconductor apparatus, cutting the manufacturing cost for the semiconductor apparatus, and increasing alignment accuracy among the three diffusion layers.

In addition, in Embodiment 3, the diffusion layer with successively varied diffusion depth can be formed together with other diffusion layers in one ion implantation step, thereby simplifying the forming process of the diffusion layers of elements with various characteristics.

In Embodiment 3, the exposure mask M4b including the light passing sections A and the translucent section P4b with successively varied optical transmissivity in part is used as an exposure mask of the resist material applied on the semiconductor substrate 1; however, it is also possible to use an exposure mask in which the optical transmissivity is successively varied over the entire translucent section P4b.

Further, each of the embodiments described above illustrates a case where one ion implantation is performed using one ion implantation mask. However, in the case where a resist film including a resist opening and a resist thin film section is used as an ion implantation mask as described above, it is possible to use the same resist film as an ion implantation mask and perform ion implantation a plurality of times, changing at least one of the ion type and ion implantation energy.

As described above, the present invention is exemplified by the use of its preferred Embodiments 1 to 3. However, the present invention should not be interpreted solely based on Embodiments 1 to 3 described above. It is understood that the scope of the present invention should be interpreted solely based on the claims. It is also understood that those skilled in the art can implement equivalent scope of technology, based on the description of the present invention and common knowledge from the description of the detailed preferred Embodiments 1 to 3 of the present invention. Furthermore, it is understood that any patent, any patent application and any references cited in the present specification should be incorporated by reference in the present specification in the same manner as the contents are specifically described therein.

### INDUSTRIAL APPLICABILITY

The present invention can be applied in the field of an ion implanting method that adjusts a profile of an ion implanting area using a difference in height of a resist film as an ion implantation mask, and a method for manufacturing a semiconductor apparatus using the ion implanting method. According to the present invention, the plurality of diffusion layers with different concentration profiles can be formed in one photolithography step and one ion implantation step, thereby reducing a manufacturing period (TAT) of the semiconductor apparatus, cutting a manufacturing cost for the semiconductor apparatus, and increasing alignment accuracy between two diffusion layers.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. An ion implantation method for selectively implanting ions in a semiconductor area, which is a semiconductor substrate or a semiconductor layer formed on a semiconductor substrate, using an ion implantation mask, the method comprising the steps of:
forming the ion implantation mask by exposing and developing of a photosensitive material film, in such a manner that the ion implantation mask includes a mask opening and a mask thin film section; and
implanting ions using the ion implantation mask as a mask to form a plurality of diffusion layers with different diffusion depths in the semiconductor area corresponding to the mask opening section and the mask thin film section.

2. An ion implantation method according to claim 1, wherein, in the step of implanting ions, a first diffusion layer with a deep diffusion depth is formed in a portion of the semiconductor area corresponding to the mask opening of the ion implantation mask, and a second diffusion layer with a shallow diffusion depth is formed in a portion of the semiconductor area corresponding to the mask thin film section of the ion implantation mask.

3. An ion implantation method according to claim 1, wherein the diffusion depth of the second diffusion layer is a depth in accordance with a thickness of the mask thin film section of the ion implantation mask.

4. An ion implantation method according to claim 1, wherein the mask thin film section is constituted of a plurality of thin film portions with different film thicknesses.

5. An ion implantation method according to claim 4, wherein the mask thin film section is constituted of a first thin film portion with a first film thickness, and a second thin film portion with a second film thickness, which is different from the first film thickness.

6. An ion implantation method according to claim 5, wherein the mask thin film section is formed such that the second thin film portion is thinner than the first thin film portion, and the film thickness of the second thin film portion either decreases or increases incrementally from one end to the other end.

7. An ion implantation method according to claim 5, wherein the mask thin film section is formed such that the second thin film portion is thinner than the first thin film portion, and the film thickness of the second thin film portion either decreases or increases successively from one end to the other end.

8. An ion implantation method according to claim 1, wherein the mask thin film section has a structure such that the film thickness of the mask thin film section either decreases or increases incrementally from one end to the other end.

9. An ion implantation method according to claim 1, wherein the mask thin film section has a structure such that the film thickness of the mask thin film section either decreases or increases successively from one end to the other end.

10. An ion implantation method according to claim 1, wherein:
the photosensitive material is a positive type resist in which a portion exposed to exposure light is removed by developing; and
in the step of exposing and developing of the photosensitive material film, the positive type resist formed on the semiconductor area is exposed and developed using an exposure mask including alight passing section for allowing the exposure light to pass through and a translucent section for decreasing the exposure light, to form a resist film, as the ion implantation mask, including a resist opening corresponding to the light passing section and a resist thin film section corresponding to the translucent section.

11. An ion implantation method according to claim 10, wherein the exposure mask includes the translucent section for decreasing the exposure light, in which a half tone mask for decreasing the exposure light evenly over the entire translucent section is used in the translucent section.

12. An ion implantation method according to claim 10, wherein the exposure mask is formed such that a light shielding film for shielding the exposure light is selectively formed on a transparent substrate, which is constituted of a transparent member that allows the exposure light to pass through.

13. An ion implantation method according to claim 12, wherein the exposure mask has a structure such that the light passing section is defined as the opening of the light shielding film and the translucent section is formed by alternately arranging light passing areas, from which the light shielding film is removed, and light shielding areas, in which the light shielding film remains, lengthwise and widthwise.

14. An ion implantation method according to claim 12, wherein the exposure mask has a structure such that the light passing section is defined as the opening of the light shielding film and the translucent section is formed by alternately arranging stripe-formed light passing areas, from which the light shielding film is removed, and stripe-formed light shielding areas, in which the light shielding film remains, in a given direction.

15. An ion implantation method according to claim 1, wherein, in the step of implanting ions, a plurality of diffusion layers with different diffusion depths are formed by the ion implantation by a constant implantation energy.

16. An ion implantation method according to claim 1, wherein, in the step of implanting ions, ion implantation is performed a plurality of times by changing at least one of the implantation energy and anion type, using the same ion implantation mask.

17. A method for manufacturing a semiconductor apparatus including a plurality of elements, the method comprising an ion implantation step of selectively implanting ions in a semiconductor area, which is a semiconductor substrate or a semiconductor layer formed on the semiconductor substrate, using an ion implantation mask, to form a diffusion layer, which constitutes the elements, in the semiconductor area,
the ion implanting step comprising the steps of:
forming the ion implantation mask by exposing and developing of a photosensitive material film, in such a manner that the ion implantation mask includes a mask opening and a mask thin film section; and
implanting ions using the ion implantation mask as a mask to form a plurality of diffusion layers with different diffusion depths in the semiconductor area corresponding to the mask opening section and the mask thin film section.
